(19) United States
(12) Patent Application Publication
(10) Pub. No.: US 2007/0075312 A1
(43) Pub. Date: Apr. 5, 2007

(54) Full-Color OLED Display Apparatus with Improved Color Saturation and a Method of Manufacturing the Same

(75) Inventors: Chih-Ming Chin, Chu Nan (TW); Joel Chia-Yeh Chang, Chu Nan (TW); Ting-Chou Chen, Chu Nan (TW); Wen-Jeng Lan, Chu Nan (TW); Chien-Chih Chiang, Chu Nan (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: UNIVISION TECHNOLOGY INC., Chu Nan (TW)

(21) Appl. No.: 11/534,771

(22) Filed: Sep. 25, 2006

(30) Foreign Application Priority Data
Sep. 30, 2005 (TW) 94134373

(51) Int. Cl. H01L 29/08

(52) U.S. Cl. 257/40

(57) ABSTRACT

This invention relates to a full-color OLED display apparatus with improved color saturation and a method of manufacturing the same. The OLED display apparatus comprises a plurality of pixels positioned on the substrate. A first electrode, a first organic light emitting layer, a second organic light emitting layer, a third organic light emitting layer, and a second electrode are arranged on the substrate of each pixel in sequence. Moreover, a first sub pixel, a second sub pixel, and a third sub pixel are defined on the first electrode. To enhance color saturation of the OLED display apparatus, in the OLED display apparatus, the second organic light emitting layer is arranged on the second sub pixel area; the third organic light emitting layer is arranged on the second sub pixel area and the third sub pixel area; and the first organic light emitting layer is arranged on the first sub pixel area and the second sub pixel area.

### RELATED APPLICATIONS

The present application is based on, and claims priority from, Taiwan Application Serial Number 94134373, filed Sep. 30, 2005, the disclosure of which is hereby incorporated by reference herein in its entirety.

### BACKGROUND

1. Field of Invention

The present invention relates to a full-color OLED display apparatus with improved color saturation and a process of fabricating the same.

2. Description of Related Art

The key point of successfully developing a display apparatus is how to achieve full-color effect. There three common ways for OLED to achieve full-color:

1. Emission of three primary colors by independent pixels: the OLED devices of three primary colors (red, green, and blue) are positioned side by side. In addition, the lights of these three colors are mixed in appropriate ratio to obtain full-color effect.

However, an OLED display apparatus needs to be processed by evaporating and masking several times to produce different color organic light emitting layer. Thus, the manufacturing process is complicated. In addition to that, the accuracy of alignment required by evaporating and masking processes has to be very high so low yield and high cost are expected.

2. Color conversion: A color change media (CCM) is excited by a blue OLED device as the light source to obtain three primary visible lights, red, green, and blue. Therefore, full-color effect can be obtained.

However, the energy difference between the blue light source and red light is large, so the efficiency is low while converting the blue light source into the red one, which affects the brightness of OLED.

3. Color filter: at least one OLED device which emits white light is installed as a back light source. By using the well developed color filter technique, the white light source can be filtered by the color filter to obtain full-color effect.

FIG. 1 illustrates the common structure of an OLED display apparatus with color filter for light filtering. Color filter 10 comprises a black matrix 13 arranged on a substrate 11 and a color filter layer 15 disposed on the substrate 11 where no black matrix 13 is arranged on. The color filter layer 15 comprises a first photo resist 151, a second photo resist 153, and a third photo resist 155. In addition, a flat barrier unit 17, which is over coat and/or a barrier layer, is optionally arranged above the black matrix 13 and the color filter layer 15 so following processes can be performed more easily.

Besides, a first electrode 21 of an OLED device 20 is arranged on the flat barrier unit 17. An organic light emitting layer 23 and a second electrode 25 are placed on a partial surface of the first electrode 21 in sequence. The organic light emitting layer 23 projects a white light source S by applying a working current from the first electrode 21 to the second electrode 25. After transmitting through the color filter layer 15, the white light source S will be filtered and become three primary lights, green (L1), blue (L2), and red (L3), respectively. By arranging and combining these three primary colors, full-color display of OLED display apparatus 200 can be obtained.

By using color filter 10, the OLED display apparatus 200 only requires an organic light emitting layer 23 to generate white light source S. Therefore, it requires few evaporating processes, and also avoids the difficulty of accurate alignment while evaporating or masking. However, because the wavelength of the white light source S covers wide range, the transmittance through the color filter layer 15 is low. This affects the brightness and the saturation of the OLED display apparatus 200, therefore, the emission quality can not be enhanced efficiently.

### SUMMARY

For the forgoing reasons, the present invention relates to a new full-color OLED display apparatus with improved saturation. This not only avoids the difficulties of alignment while masking but also enhances yield rate and transmittance of the photo resist of the light source. This is the characteristics of the present invention.

A full-color OLED display apparatus with improved color saturation, having a plurality of pixels arranged on a substrate, wherein each one of the pixels comprises a first electrode arranged on the substrate; an organic light emitting layer arranged on the first electrode; and a second electrode arranged on the organic light emitting layer. In addition, the first electrode comprises a first sub pixel area, a second sub pixel area, and a third sub pixel area. The organic light emitting layer comprises a first organic light emitting layer arranged on the first sub pixel area and the second sub pixel area; a second organic light emitting layer arranged on the second sub pixel area; and a third organic light emitting layer arranged on the second sub pixel area and the third sub pixel area.

A method of manufacturing a full-color OLED display apparatus with improved color saturation comprises forming a plurality of pixels on a substrate, wherein a process of forming each one of the pixels comprises: forming a first electrode on the substrate; defining the first pixel area, a second pixel area, and a third pixel area on the first electrode; using a second mask to cover the first sub pixel area and the third pixel sub area; aligning the second sub pixel area with the second evaporating source and performing an evaporating process of a second organic light emitting layer to form the second organic light emitting layer; using a third mask to cover the first pixel area; aligning the second sub pixel area and the third sub pixel area with the third evaporating source and performing an evaporating process of a third organic light emitting layer to form the third organic light emitting layer; using a first mask to cover the third sub pixel area; aligning the first sub pixel area and the second sub pixel area with the first evaporating source and performing an evaporating process of a first organic light emitting layer to form the first organic light emitting layer; and forming a second electrode on the first organic light emitting layer, the second organic light emitting layer, and the third organic light emitting layer.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a cross-section perspective view of an OLED display apparatus in the prior art;

FIG. 2 is a cross-section perspective view of a full-color OLED display apparatus with improved color saturation, according to one embodiment of this invention;

FIG. 3 is a cross-section perspective view of an embodiment of this invention;

FIG. 4 is a cross-section perspective view of an embodiment of this invention;

FIG. 5 is a cross-section perspective view of an embodiment of this invention;

FIG. 6A to FIG. 6C are cross-section perspective views of a full-color OLED display apparatus with improved color saturation of this invention during an evaporating process.

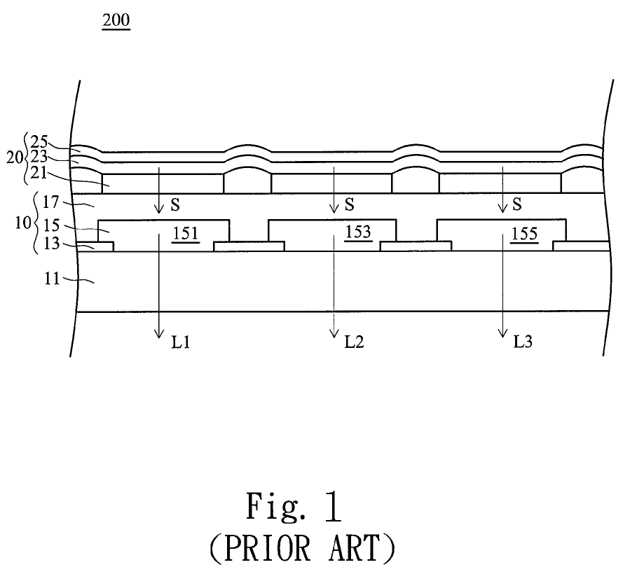

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

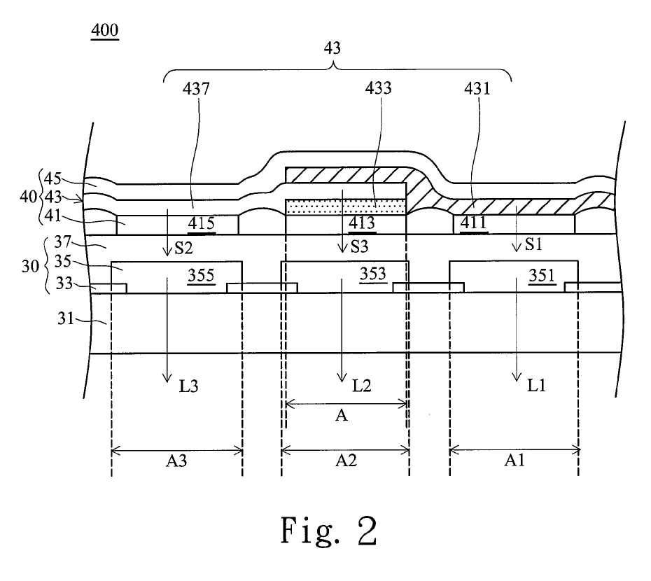

First, referring to FIG. 2, it illustrates the cross-section perspective view of one embodiment of the present invention, which shows a full-color OLED display apparatus with improved color saturation. In order to clarify the embodiments of the present invention, the figure of the present invention represents one pixel. As shown in FIG. 2, the OLED display apparatus 400 comprises a substrate 31 and an OLED device 40. The OLED device 40 comprises a first electrode 41, an organic light emitting layer 43, and a second electrode 45, wherein the organic light emitting layer 43 comprise a first organic light emitting layer 431, a second organic light emitting layer 433, and a third organic light emitting layer 437.

The first electrode 41 is arranged on the substrate 31. In addition, the first electrode 41 is defined as a first sub pixel area 411, a second sub pixel area 413, and a third sub pixel area 415. The first organic light emitting layer 431 is disposed on the first sub pixel area 411 and the second sub pixel area 413. Moreover, the second organic light emitting layer 433 is disposed on the second sub pixel area 413. Finally, the third organic light emitting layer 437 is disposed on the second sub pixel area 413 and the third sub pixel area 415.

The first organic light emitting layer 431, the second organic light emitting layer 433, and the third organic light emitting layer 437 are arranged on the second sub pixel area 413 by overlapping. Therefore, the first organic light emitting layer 431 and the third organic light emitting layer 437 can be optionally arranged on the firs electrode 41 of the second sub pixel area 413 in sequence. In addition, the second organic light emitting layer 433 is arranged between the first organic light emitting layer 431 and the first electrode 41, or arranged between the first organic light emitting layer 431 and the third organic light emitting layer 437, or arranged on the third organic light emitting layer 437. Certainly, as regards the arrangement on the second sub pixel area 413, the third organic light emitting layer 437 and the first organic light emitting layer 431 can also be disposed on the first electrode 41 of the second sub pixel area 413 in sequence. The second organic light emitting layer 433 is arranged between the third organic light emitting layer 437 and the first electrode 41, or arranged between the third organic light emitting layer 437 and the first organic light emitting layer 431, or arranged on the first organic light emitting layer 431. According to FIG. 2, the second organic light emitting layer 433, the third organic light emitting layer 437, and the first organic light emitting layer 431 are arranged on the first electrode 41 of the second sub pixel area 413 in sequence.

While working current is applied between the first electrode 41 and the second electrode 45, the first organic light emitting layer 431 will generate a first light source S1, and the third organic light emitting layer 437 will generate a second light source S2, and the overlap of the first organic light emitting layer 431, the second organic light emitting layer 433, and the third organic light emitting layer 437, it will generate a third light source S3.

In the embodiment of the present invention, the OLED display apparatus 400 further comprises a color filter 30 arranged between the substrate 31 and the OLED device 40. The color filter 30 comprises a first color filter layer (or called photo resist) 35 which provides the light filtering function, and at least one black matrix 33. The black matrix 33 is arranged on the substrate 31, and the first color filter layer 35 is arranged on the substrate 31 and the black matrix 33. The first color filter layer 35 comprises a first photo resist 351, a second photo resist 353, and a third photo resist 355. The first photo resist 351 is disposed on the vertically extended region of the first sub pixel area 411. The second photo resist 353 is disposed on the vertically extended region of the second sub pixel area 413. The third photo resist 355 is disposed on the vertically extended region of the third sub pixel area 415. The black matrix 33 and the first color filter layer 35 can be covered by a flat barrier unit 37, such as an over coat, a barrier layer or both.

Therefore, the first light source S1 generated by the first organic light emitting layer 431 can penetrate the first photo resist 351 directly, and be filtered to generate a first light L1. The second light source S2 generated by the third organic light emitting layer 437 can penetrate the third photo resist 355, and be filtered to generate a third light L3. In addition, the first organic light emitting layer 431, the second organic light emitting layer 433, and the third organic light emitting layer 437 are overlapped on the second sub pixel area 413 to generate a third light source S3. The third light source S3 will be filtered to generate a second light L2 after penetrating the second photo resist 353. The full-color display effect of the OLED display apparatus 400 can be achieved by mixing the first light L1, the second light L2, and the third light L3. By using the color filter 30, the light source of each color generated by the organic light emitting layer 43 can be adjusted to enhance color saturation of the OLED display apparatus. In addition, it can also avoid the color cast resulted from the attenuate inconsistency of each light source.

In an embodiment of the present invention, the first light source S1 and the second light source S2 are complementary to each other. For example, they are a blue light source and an orange, yellow or red light source, respectively. Moreover, the first photo resist 351, the second photo resist 353, and the third photo resist 355 are a blue, a green, and a red photo resist, respectively.

Since both the first light source S1 (blue light source) and the second light source S2 (orange or yellow or red light source) provide better transmittance through the first photo resist 351 (blue photo resist), and a third photo resist 355 (red photo resist). Thus, the brightness of the OLED display apparatus 400 can be enhanced more efficiently.

In addition to that, the color of light generated from the second organic light emitting layer 433 can be adjusted according to the color of the photo resist disposed underneath thereof. In other words, the color of light generated from the second organic light emitting layer 433 and the color of the second photo resist 353 are in the same color system to enhance the brightness of the second light L2. For example, when the second photo resist 353 is a green photo resist, the second organic light emitting layer 433 is selected as a light emitting layer which generates a green light source. Thus, according to the suitable range for the OLED display apparatus 400, the brightness of the second light L2 can be enhanced. In other words, the brightness of the green light in the OLED display apparatus 400 will be enhanced.

However, for the convenience of following manufacturing processes, the second organic light emitting layer 433 is not only disposed on the second sub pixel area 413, but also can be extended to the first sub pixel area 411 and the third sub pixel area 415.

In addition, while arranging the organic light emitting layer 43, the functional area of the organic light emitting layer with better light emitting efficiency can be adjusted. For example, when the second organic light emitting layer 433 is an organic light emitting layer with better efficiency, the functional area of the second organic light emitting layer 433, A, can be adjusted, which results in the functional area of the second organic light emitting layer 433, A, smaller than the functional areas of the second photo resist 353, the first photo resist 351, or the third photo resist 355, A2, A1, or A3. Thus, the difficulties of masking and alignment for the second organic light emitting layer 433 will be reduced.

Moreover, the organic light emitting layers in the first organic light emitting layer 431 and the second organic light emitting layer 433 or the third organic light emitting layer 437 can be selected from a doped organic light emitting layer by doping at least one host emitter (H) with at least one dopant (D).

In one embodiment of the present invention, it further comprises a plurality of thin film transistors (TFT) (not illustrated), each TFT is electrically connected with the first electrode 41 of the first sub pixel area 411, the second sub pixel area 413 or the third sub pixel area 415 respectively to form an active matrix OLED display apparatus 400. Furthermore, the active matrix OLED display apparatus can be manufactured by the method of color filter on array (COA) or array on color filter (AOC).

The first organic light emitting layer 431 and the third organic light emitting layer 437 are arranged on the first sub pixel area 411 and the second sub pixel area 413, and the second sub pixel area 413 and the third sub pixel area 415, respectively. Therefore, the first organic light emitting layer 431 and the third organic light emitting layer 437 have larger disposing areas compared with the conventional structure wherein each organic light emitting layer is arranged independently. Thus, the difficulties of aligning the first organic light emitting layer 431 and the third organic light emitting layer 437 while masking can be avoided. The yield of the manufacture is also enhanced.

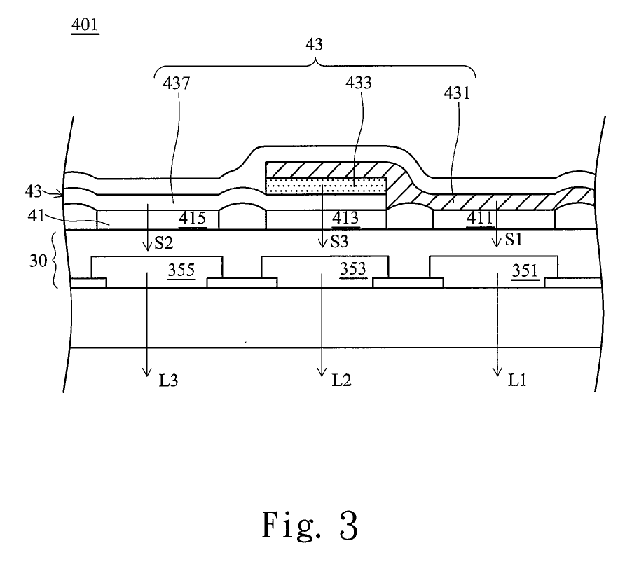

As mentioned above, the first organic light emitting layer 431, the second organic light emitting layer 433 and the third organic light emitting layer 437 are arranged by overlapping. Therefore, the third organic light emitting layer 437 is arranged on the first electrode 41 of the second sub pixel area 413 first, and then the second organic light emitting layer 433 and the first organic light emitting layer 431 to form an OLED display apparatus 401, as show in FIG. 3.

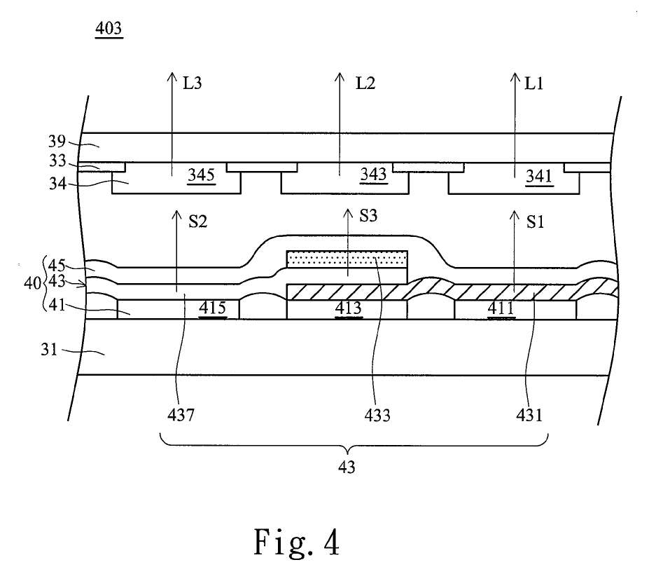

Next, referring to FIG. 4, it illustrates a cross-section perspective view of another embodiment of the present invention. As shown in FIG. 4, the OLED display apparatus 403 comprises a substrate 31 and an OLED device 40 arranged in the same way as the substrate 31 and the OLED device 40 in FIG. 2. However, with regard to the arrangement of the first organic light emitting layer 431, the second organic light emitting layer 433, and the third organic light emitting layer 437 on the second sub pixel area 413 by overlapping, in FIG. 4, the first organic light emitting layer 431, the third organic light emitting layer 437, and the second organic light emitting layer 433 are arranged on the first electrode 41 in sequence, which is different from the arrangement in FIG. 2. Certainly, the arrangement in FIG. 2 or the description above is also applicable to the first organic light emitting layer 431, the second organic light emitting layer 433, and the third organic light emitting layer 437.

The OLED display apparatus 403 further comprises a packing cover 39 arranged on the substrate 31 to enclose the OLED device 40. The OLED device 40 can be protected by the arrangement of packing cover 39. Moreover, there is a second color filter layer 34 arranged underneath the packing cover 39, and the second color filter layer 34 comprises the fourth photo resist 341, the fifth photo resist 343, and the sixth photo resist 345. The fourth photo resist 341 is corresponded to the vertically extended region of the first sub pixel area 411. The fifth photo resist 343 is corresponded to the vertically extended region of the second sub pixel area 413. The sixth photo resist 345 is corresponded to the vertically extended region of the third sub pixel area 415.

The fourth photo resist 341, the fifth photo resist 343, and the sixth photo resist 345 are used to filter the first light source S1, the third light source S3, and the second light source S2 generated by the organic light emitting layer 43 respectively. The second electrode 45 can be made of a transparent conductive material. Hence, the first light source S1, the second light source S2, and the third light source S3 can transmit through the second electrode 45 to achieve the goal of top-emission of the OLED display apparatus 403.

In the embodiment of the present invention, it further comprises a plurality of TFT (not illustrated), and each TFT is electrically connected with the first electrode 41 of the first sub pixel area 411, the second sub pixel area 413 or the third sub pixel area 415 respectively to form an active matrix OLED display apparatus 403.

The color of light generated from the second organic light emitting layer 433 can be adjusted according to the color of the fifth photo resist 343. In other words, the color of light generated from the second organic light emitting layer 433 and the fifth photo resist 343 are in the same color system to enhance the brightness of the second light L2. For example, when the fifth photo resist 343 is optionally a green photo resist, the second organic light emitting layer 433 is selected as a light emitting layer which generates a green light source. Thus, according to the suitable range for the OLED display apparatus 400, enhancing the brightness of the second light L2 indicates that the brightness of the green light of the OLED display apparatus 403 is also enhanced.

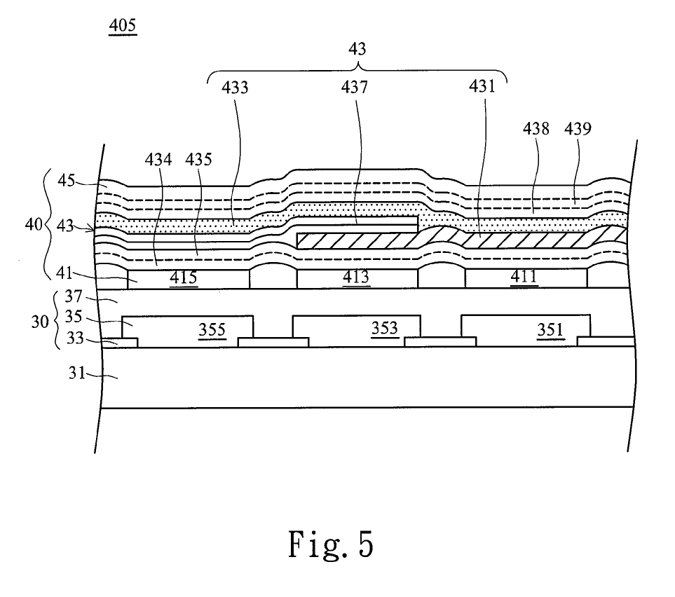

Next, referring to FIG. 5, it depicts the cross-section perspective view of another embodiment of the present invention. In this embodiment, the arrangement of the substrate 31, the color filter 30, and the first electrode 41 are the same as that of FIG. 2, so detailed description of this arrangement will not be repeated herein. As shown in FIG. 5, in this embodiment, the first organic light emitting layer 431 is arranged on the first sub pixel area 411 and the second sub pixel area 413. After that, the third organic light emitting layer 437 is arranged on the second sub pixel area 413 and the third sub pixel area 415. Next, the second organic light emitting layer 433 is arranged on the first sub pixel area 411, the second sub pixel area 413 and the third sub pixel area 415. In addition, the first photo resist 351, the second photo resist 353, and the third photo resist 355 are corresponded to the vertically extended regions of the first sub pixel area 411, the second sub pixel area 413, and the third sub pixel area 415, respectively.

Moreover, the second organic light emitting layer 433 can be optionally disposed on the vertically extended regions of any two sub pixel areas or on the vertically extended region of three sub pixel areas, which means that the second organic light emitting layer 433 can be disposed on the second sub pixel area 413, on the first sub pixel area 411 and the second sub pixel area 413, on the second sub pixel area 413 and the third sub pixel area 415, or on the first sub pixel area 411, the second sub pixel area 413 and the third sub pixel area 415 for the convenience of following manufacturing processes.

Moreover, the inside of the OLED device 40 can optionally comprise a hole injection layer (HIL) 434, a hole transporting layer (HTL) 435, an organic light emitting layer, an electron transporting layer (ETL) 438, an electron injection layer (EIL) 439, and one of the combinations above between the first electrode 41 and the second electrode 45. For example, before the organic light emitting layer 43 is disposed, at least one hole injection layer 434 and one hole transporting layer 435 are disposed on the first electrode 41 in sequence. Then, the organic light emitting layer 43 is arranged on the hole transporting layer 435. After finished arranging the organic light emitting layer 43, at least one electron transporting layer 438 and one electron injection layer 439 are arranged on the organic light emitting layer 43 in sequence. Finally, the second electrode 45 is arranged on the electron injection layer 439.

The organic light emitting layer 43 is selected as a single-layer organic light emitting layer or a multi-layer overlapping organic light emitting layer. For example, the first organic light emitting layer 431 and the second organic light emitting layer 433 are single-layer organic light emitting layers. However, the third organic light emitting layer 437 is a multi-layer overlapping organic light emitting layer. As showing in FIG. 5, the third organic light emitting layer 437 is a double-layer overlapping organic light emitting layer.

Meanwhile, referring to FIG. 2 and FIG. 4, when a color filter 30 which comprises first color filter layer 35 is arranged between the substrate 31 and the OLED device 40 as the OLED display apparatus 400 in FIG. 2, it is a bottom-emission OLED display apparatus 400. Meanwhile, when a packing cover 39 which comprises a second color filter layer 34 is arranged on the substrate 31 to cover the OLED device 40 as the OLED display apparatus 403 in FIG. 4, it is a top-emission OLED display apparatus 403. Certainly, while the color filter 30 comprising the first color filter layer 35 is arranged between the substrate 31 and the OLED device 40, a packing cover 39 comprising a second color filter layer 34 can be arranged on the substrate 31 to cover the OLED device 40 at the same time. Therefore, the goal of double-faced OLED display apparatus is achieved.

In the double-faced OLED display apparatus, a plurality of TFT can be also arranged (not illustrated). Each TFT is electrically connected with the first electrode 41 of the first sub pixel area 411, the second sub pixel area 413 or the third sub pixel area 415 respectively to form an active matrix OLED display apparatus.

In the embodiments above, the positions of the first sub pixel area 411, the second sub pixel area 413, and the third sub pixel area 415 can be changed and the photo resist 351, 353, 355, 341, 343, and 345 are also changed correspondingly. For example, the second sub pixel area 413 is arranged between the first sub pixel area 411 and the third sub pixel area 415, or the first sub pixel area 411 is arranged between the second sub pixel area 413 and the third sub pixel area 415, or the third sub pixel area 415 is arranged between the first sub pixel area 411 and the second sub pixel area 413. Surely, while the positions of the sub pixel areas 411, 413, and 415 are changed, the arrangements of the first organic light emitting layer 431, the second organic light emitting layer 433, and the third organic light emitting layer 437 are also changed correspondingly according to the positions of the sub pixel areas 411, 413, and 415.

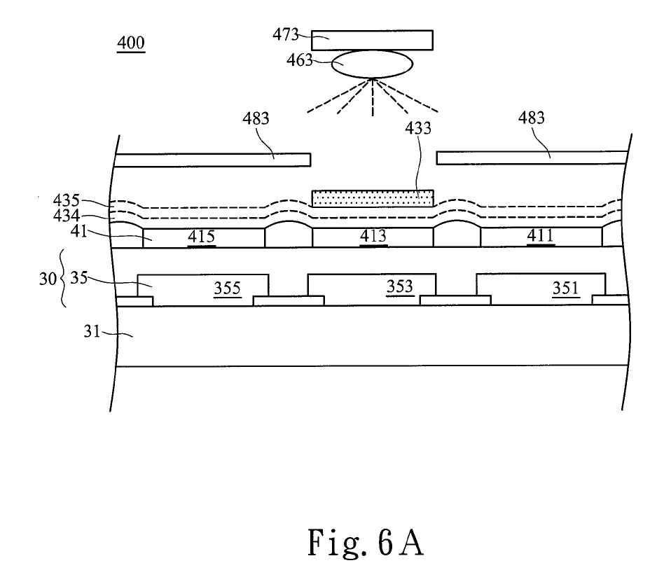

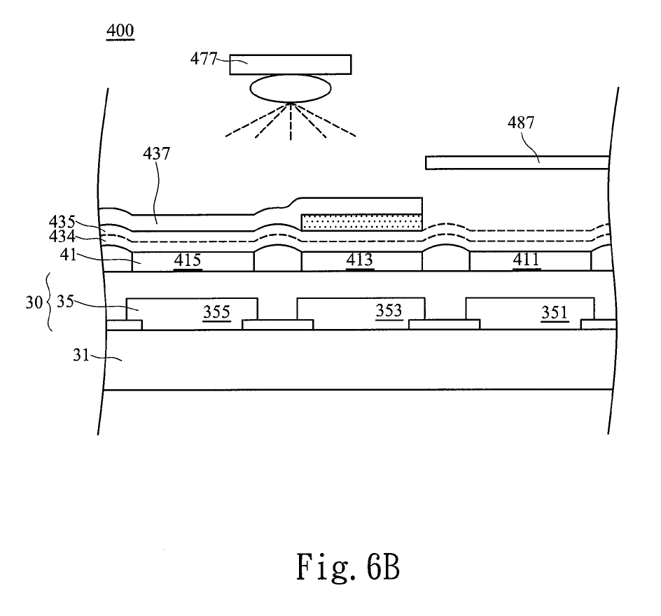

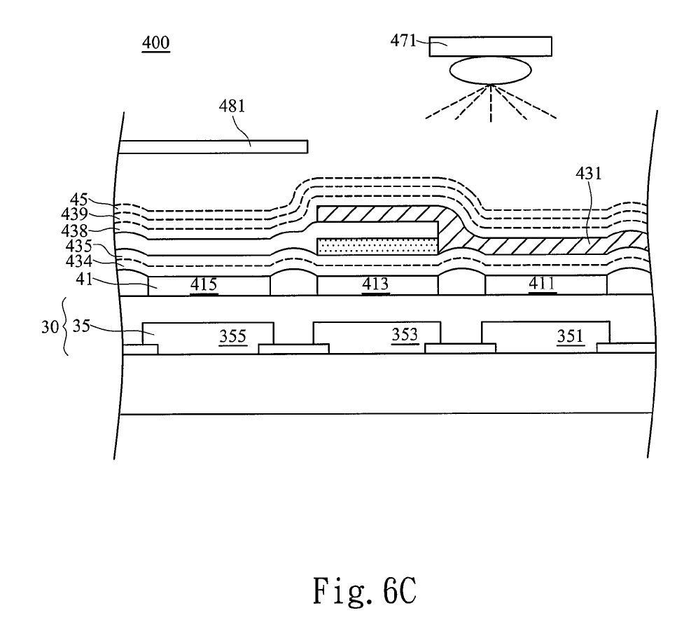

Finally, referring to FIG. 6A to FIG. 6C, they depict the cross-section view of a full-color display apparatus with improved color saturation of the present invention in evaporating process. In order to clarify the embodiments of the present invention, the figures of the present invention represent one pixel. As shown in figures, the process of manufacturing the OLED display apparatus 400 of the present invention comprises a hole injection layer 434 and/or a hole transporting layer 435 arranged on the first electrode 41 by evaporating, after the first electrode 41 of the OLED display apparatus 400 is arranged. In addition, the first organic light emitting layer 431, the second organic light emitting layer 433, and the third organic light emitting layer 437 are arranged on the hole transporting layer 435, wherein the first electrode 41 defines the first sub pixel area 411, the second sub pixel area 413, and the third sub pixel area 415.

First, a second mask 483 is arranged on the vertically extended area of the first sub pixel area 411 and the third sub pixel area 415, and the second organic light emitting layer 433 is evaporated by a second evaporating source 473. Meanwhile, the second organic light emitting layer 433 is formed on the first electrode 41 of the vertically extended region of the second sub pixel area 413, wherein the second organic light emitting material 463 of the second evaporating source 473 is selected on the basis of the color of the second photo resist 353. For instance, when the second photo resist 353 is a green photo resist, the second organic light emitting material 463 is selected as an organic light emitting material which generates a green light source, as show in FIG. 6A.

A third mask 487 is arranged on the vertically extended region of the first sub pixel area 411, and then a third organic light emitting layer 437 is evaporated by a third evaporating source 477. Meanwhile, the third organic light emitting layer 437 is formed on the vertically extended region of the second sub pixel area 413 and the third sub pixel area 415, as shown in FIG. 6B.

Next, a first mask 481 is arranged on the vertically extended region of the third sub pixel area 415, and then a first organic light emitting layer 431 is evaporated by a first evaporating source 471. Meanwhile, a first organic light emitting layer 431 is formed on the vertically extended region of the first sub pixel area 411 and the second sub pixel area 413, as shown in FIG. 6C.

Certainly, in the embodiment of the present invention, a hole injection layer 434 and/or a hole transporting layer 435 can be formed on the first electrode 41, before the first organic light emitting layer 431, the second organic light emitting layer 433, and the third organic light emitting layer 437 are evaporated, as shown by a dotted line. After that, the first organic light emitting layer 431, the second organic light emitting layer 433, and the third organic light emitting layer 437 are formed on the hole injection layer 434 or the hole transporting layer 435.

After finished arranging the first organic light emitting layer 431, the second organic light emitting layer 433, and the third organic light emitting layer 437, the manufacturing process of the OLED display apparatus 400 is continued. For instance, an electron transporting layer 438 and/or an electron injection layer 439, and the second electrode 45 are formed in sequence on the first organic light emitting layer 431, the second organic light emitting layer 433, and the third organic light emitting layer 437 by evaporating, as shown by the dotted line. Thus, the OLED display apparatus 400 is constructed.

In practice, the order for arranging the first organic light emitting layer 431, the second organic light emitting layer 433 and the third organic light emitting layer 437 can be changed. For example, the third organic light emitting layer 437 is disposed first, and then the first organic light emitting layer 431 is arranged. In addition, the process of manufacturing the second organic light emitting layer 433 can follow the method shown in FIG. 6A to FIG. 6C, wherein it is arranged before the third organic light emitting layer 437, or before the first organic light emitting layer 431, or after the first organic light emitting layer 431 but before the step of manufacturing the second electrode 45.

Surely, it is also able to process the step of disposing the first organic light emitting layer 431 first, and then the step of disposing the third organic light emitting layer 437. The manufacturing process of the second organic light emitting layer 433 can be arranged before the first organic light emitting layer 431, or before the third organic light emitting layer 437, or before the manufacturing process of the second electrode 45.

Compared with the method of manufacturing an OLED display apparatus in the art, wherein the red, green, and blue organic light emitting layers are disposed independently, the evaporating process of the organic light emitting layer 43 avoids the difficulties of alignment while evaporating. Therefore, yield of the full-color OLED display apparatus 400 can be raised. In addition, it can also enhance transmittance and color saturation of the light source of the organic light emitting layer. Hence, the power consumption for emitting light is reduced, and the lifetime of the OLED display apparatus will be prolonged.

Certainly, the manufacturing process above can also be applied to the active matrix OLED display apparatus, wherein the first organic light emitting layer, the second organic light emitting layer, and the third organic light emitting layer are formed similarly in sequence, so detailed description is not repeated herein.

In conclusion, the present invention relates to a full-color OLED display apparatus with improved color saturation. It not only enhances the brightness and color levels, but also enhances yield.

Although the present invention has been described in considerable detail with reference and certain preferred embodiments thereof, other embodiments are possible. Therefore, their spirit and scope of the appended claims should no be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A full-color OLED display apparatus with improved color saturation, having a plurality of pixels arranged on a substrate, wherein each one of the pixels comprises:
a first electrode, arranged on the substrate, wherein the first electrode comprises a first sub pixel area, a second sub pixel area, and a third sub pixel area;
an organic light emitting layer, arranged on the first electrode, wherein the organic light emitting layer comprises:
a first organic light emitting layer, arranged on the first sub pixel area and the second sub pixel area;
a second organic light emitting layer, arranged on the second sub pixel area; and
a third organic light emitting layer, arranged on the second sub pixel area and the third sub pixel area; and
a second electrode, arranged on the organic light emitting layer.

2. The full-color OLED display apparatus of claim 1, wherein the second organic light emitting layer is arranged between the first organic light emitting layer and the first electrode, or arranged between the first organic light emitting layer and the third organic light emitting layer, or arranged on the third organic light emitting layer when the first organic light emitting layer and the third organic light emitting layer is arranged on the second sub pixel area in sequence; and the second organic light emitting layer is arranged between the third organic light emitting layer and the first electrode, or arranged between the third organic light emitting layer and the first organic light emitting layer, or arranged on the first organic light emitting layer, when the third organic light emitting layer and the first organic light emitting layer is arranged on the second sub pixel area in sequence.

3. The full-color OLED display apparatus of claim 1, wherein the arrangement of the second organic light emitting layer is extended on the vertically extended regions of the first sub pixel area, the second sub pixel area, and the third sub pixel area.

4. The full-color OLED display apparatus of claim 1, wherein the arrangement of the second organic light emitting layer is extended on the vertically extended regions of the first sub pixel area and the second sub pixel area, or on the vertically extended regions of the second sub pixel area and the third sub pixel area.

5. The full-color OLED display apparatus of claim 1, further comprising a color filter arranged between the substrate and first electrode, wherein the color filter comprises a first color filter layer and the first color filter layer comprises a first photo resist, a second photo resist, and a third photo resist arranged on the vertically extended regions of the first sub pixel area, the second sub pixel area, and the third sub pixel area respectively.

6. The full-color OLED display apparatus of claim 5, further comprising a plurality of thin film transistor, and each one of TFT electrically connected with the first electrode of the first sub pixel area, the second sub pixel area or the third sub pixel area respectively.

7. The full-color OLED display apparatus of claim 5, wherein the color filter further comprises at least one over coat, at least one barrier layer or one of the combinations thereof arranged on the first color filter layer.

8. The full-color OLED display apparatus of claim 5, wherein the color filter further comprises at least one black matrix on the substrate.

9. The full-color OLED display apparatus of claim 5, wherein the color of light of the light source generated from the second organic light emitting layer and the color of the second photo resist are in the same color system.

10. The full-color OLED display apparatus of claim 5, wherein the functional area of the second organic light emitting layer is smaller than one of the functional areas of the first photo resist, the second photo resist, and the third photo resist.

11. The full-color OLED display apparatus of claim 5, further comprising a packing cover arranged on the substrate, and a second color filter layer arranged underneath the packing cover wherein the second color filter layer comprises a fourth photo resist, a fifth photo resist, and a sixth photo resist arranged on the vertically extended regions of the first sub pixel area, the second sub pixel area, and the third sub pixel area respectively.

12. The full-color OLED display apparatus of claim 11, further comprising a plurality of TFT, and each one of TFT electrically connected with the first electrode of the first sub pixel area, the second sub pixel area or the third sub pixel area respectively.

13. The full-color OLED display apparatus of claim 1, further comprising a packing cover arranged on the substrate, and a second color filter layer arranged underneath the packing cover wherein the second color filter layer comprises a fourth photo resist, a fifth photo resist, and a sixth photo resist arranged on the vertically extended regions of the first sub pixel area, the second sub pixel area, and the third sub pixel area respectively.

14. The full-color OLED display apparatus of claim 13, further comprising a plurality of TFT, and each one of TFT electrically connected with the first electrode of the first sub pixel area, the second sub pixel area or the third sub pixel area, respectively.

15. The full-color OLED display apparatus of claim 13, wherein the color of the light of the light source generated from the second organic light emitting layer and the color of the fifth photo resist are in the same color system.

16. The full-color OLED display apparatus of claim 1, further comprising a hole injection layer, a hole transporting layer, an electron transporting layer, an electron injection layer, and one of the combinations thereof between the first electrode and the second electrode.

17. The full-color OLED display apparatus of claim 1, wherein the first organic light emitting layer, the second organic light emitting layer, and the third organic light emitting layer are selected from the group consisting of a single-layer organic light emitting layer, a multi-layer overlapping organic light emitting layer, and a doping doped organic light emitting layer.

18. The full-color OLED display apparatus of claim 1, wherein the first organic light emitting layer, and the third organic light emitting layer generate a first light source and a second light source respectively, and the first light source and the second light source are complementary to each other.

19. The full-color OLED display apparatus of claim 18, wherein the first light source is a blue light source, and the second light source is an orange light source, and the second organic light emitting layer generates a green light source.

20. A method of manufacturing a full-color OLED display apparatus with improved color saturation, comprising:
forming a plurality of pixels on a substrate, wherein a process of forming each one of the pixels comprises:
forming a first electrode on the substrate;
defining a first pixel area, a second pixel area, and a third pixel area on the first electrode;
using a second mask to cover the first sub pixel area and the third pixel sub area;
aligning the second sub pixel area with the second evaporating source and performing an evaporating process of a second organic light emitting layer to form the second organic light emitting layer;
using a third mask to cover the first pixel area;
aligning the second sub pixel area and the third sub pixel area with the third evaporating source and performing an evaporating process of a third organic light emitting layer to form the third organic light emitting layer;
using a first mask to cover the third sub pixel area;
aligning the first sub pixel area and the second sub pixel area with the first evaporating source and performing an evaporating process of a first organic light emitting layer to form the first organic light emitting layer; and
forming a second electrode on the first organic light emitting layer, the second organic light emitting layer, and the third organic light emitting layer.
